(19) United States
(12) Patent Application Publication
(10) Pub. No.: US 2025/0201654 A1
(43) Pub. Date: Jun. 19, 2025

(54) COOLING STRUCTURE OF A POWER SUPPLY MODULE

(71) Applicant: Murata Manufacturing Co., Ltd., Nagaokakyo-shi, Kyoto-fu (JP)

(72) Inventor: Takami MUTO, San Jose, CA (US)

(21) Appl. No.: 18/846,845

(22) PCT Filed: Jun. 16, 2023
(86) PCT No.: PCT/US2023/025529

§ 371 Date: Sep. 13, 2024

Related U.S. Application Data
(60) Provisional application No. 63/440,164, filed on Jan. 20, 2023.
(60) Provisional application No. 63/353,305, filed on Jun. 17, 2022.

(51) Int. Cl. H01L 23/367; H01L 23/373; H01L 23/538; H01L 25/18; H10D 1/20; H10D 1/68

(52) U.S. Cl. CPC H01L 23/3675; H01L 23/5385; H01L 25/18; H01L 23/373; H10D 1/20; H10D 1/68

(57) ABSTRACT

A power supply module including a first substrate, first electronic components on a principal surface of the first substrate, second electronic components above the first electronic components, and a heat sink located above the first electronic components. The first electronic components and the second electronic components are thermally connected, and the first electronic components and the heat sink are thermally connected. From a top view of the power supply module, at least a portion of one first electronic component of the first electronic components overlaps with at least a portion of one second electronic component of the second electronic components and at least a portion of the one first electronic component overlaps with a portion of the heat sink. From a side view of the power supply module, the second electronic components do not overlap any portion of the heat sink.

### CROSS REFERENCE TO RELATED APPLICATIONS

This application claims the benefit of U.S. Provisional Application No. 63/353,305, filed on Jun. 17, 2022, and U.S. Provisional Application No. 63/440,164, filed on Jan. 20, 2023. The entire contents of these applications are hereby incorporated by reference.

### BACKGROUND OF THE INVENTION

### 1. Field of the Invention

The present invention relates to power supply modules. More specifically, the present invention relates to cooling heat-generating power elements in power supply modules to thereby improve performance of the power supply modules.

### 2. Description of the Related Art

Known power supply modules include heat-generating components, such as the power elements of the power supply modules. The heat-generating components are typically spaced away from other more heat-sensitive components at locations where cavities/voids are provided to allow temperature isolation and heat dissipation of the heat-generating components. For example, inductors near the heat-generating components can be a problem because inductors can have low thermal conductivity. Some of the heat generated in the heat-generating components is also typically transferred through a substrate to a heat sink that can be connected to a carbon sheet.

For example, JP 2020-205714, as shown in FIG. 1, teaches a power converter 101 with a pair of circuit boards 10A and 10B including heat-generating power components 14 and inductive components 24. A conductive main body 23 is provided between the pair of circuit boards 10A and 10B, and heat dissipation plates 40A and 40B are respectively provided adjacent to the pair of circuit boards 10A and 10B. Heat is transferred from the pair of circuit boards 10A and 10B to the conductive main body 23 through heat-dissipation terminal blocks 50, and a heat sink 3 is affixed to the conductive main body 23 to help remove the heat from the conductive main body 23. The heat-generating power components 14 are spaced away from the inductive components 24 and arranged in an open void between the pair of circuit boards 10A and 10B to attempt to dissipate some of the heat generated by the heat-generating power components 14 with ambient air.

However, these arrangements in the known power supply modules require a large amount of space, which is not desirable when a miniaturization of the power supply modules is required. Further, if heat-generating power components must be placed close to inductive components, this decreases cooling efficiency because inductive components have low thermal conductivity. When cooling efficiency is decreased, the heat-generating power components are not able to operate at high currents.

### SUMMARY OF THE INVENTION

To overcome the problems described above, preferred embodiments of the present invention provide power supply modules that are able to be miniaturized while also having sufficient cooling such that it is still possible to generate high current.

Preferred embodiments of the present invention provide a power supply module including a first substrate, first electronic components on a principal surface of the first substrate, second electronic components above the first electronic components, and a heat sink located above the first electronic components. The first electronic components and the second electronic components are thermally connected, and the first electronic components and the heat sink are thermally connected. From a top view of the power supply module, at least a portion of one first electronic component of the first electronic components overlaps with at least a portion of one second electronic component of the second electronic components and at least a portion of the one first electronic component overlaps with a portion of the heat sink. From a side view of the power supply module, the second electronic components do not overlap any portion of the heat sink.

The first electronic components can include power elements.

The power supply module can further include third electronic components on the principal surface of the first substrate. The third electronic component can include capacitors.

The power supply module can further include a first thermally conductive material between the first electronic components and the second electronic components. The first thermally conductive material can include a first carbon sheet. The power supply module can further include a second thermally conductive material between the first electronic components and the heat sink. The second thermally conductive material can include a second carbon sheet. The first thermally conductive material and the second thermally conductive material can define a single layer.

The second electronic components can include inductors. The top surface of the heat sink can be located above a top surface of the inductors. The heat sink can have electrical conductivity and thermal conductivity. The top surface of the second electronic components and/or the top surface of the heat sink can be at least partially molded within a housing.

Preferred embodiments of the present invention also provide a power supply module including a first substrate, first electronic components and second electronic components on a principal surface of the first substrate, a second substrate above the first electronic components and the second electronic components, third electronic components on a principal surface of the second substrate, fourth electronic components above the third electronic components, and a heat sink above of the third electronic components. The third electronic components and the fourth electronic components are thermally connected, and the third electronic components and the heat sink are thermally connected. From a top view of the power supply module, at least a portion of one third electronic component of the third electronic components overlaps a portion of one fourth electronic component of the fourth electronic components and the power supply module, at least a portion of the one third electronic component overlaps a portion of the heat sink. From a side view of the power supply module, the fourth electronic components do not overlap any portion of the heat sink.

The first electronic components can include capacitors. The second electronic components can include conductive connection pins. The power supply module can further include fifth electronic components provided on the principal surface of the second substrate. The fifth electronic components can include capacitors. The power supply module can further include sixth electronic components provided on another principal surface of the second substrate opposing the principal surface of the second substrate where the third electronic components are provided. The sixth electronic component can include capacitors.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 shows an example of a known power supply module.

FIG. 2 shows a cross-sectional block diagram of a power supply module according to a first preferred embodiment of the present invention.

FIG. 3 shows a perspective view of the power supply module according to the first preferred embodiment of the present invention with the housing removed.

FIG. 4 shows a cross-sectional block diagram of a power supply module according to a second preferred embodiment of the present invention.

FIG. 5 shows a perspective view of the power supply module according to the second preferred embodiment of the present invention with the housing removed.

FIG. 6 shows a perspective view of the power supply module according to the second preferred embodiment of the present invention with the housing, the heat sink, and one of the second substrates removed.

FIG. 7 shows a cross-sectional block diagram of a power supply module according to a modification of the second preferred embodiment of the present invention.

FIG. 8 shows an example of a circuit diagram of a power supply module according to a third preferred embodiment of the present invention.

FIGS. 9 and 10 show a perspective view and a top view of a power supply module according to a fourth preferred embodiment of the present invention.

FIG. 11 shows an exploded view of the power supply module of FIG. 9.

FIGS. 12 and 13 show a perspective view and a top view of the power supply module of FIG. 9 without a heatsink.

FIG. 14 shows a simulated heatmap of a power supply module according to a fifth preferred embodiment of the present invention.

FIG. 15 shows the power supply module used to create the simulated heatmap of FIG. 14.

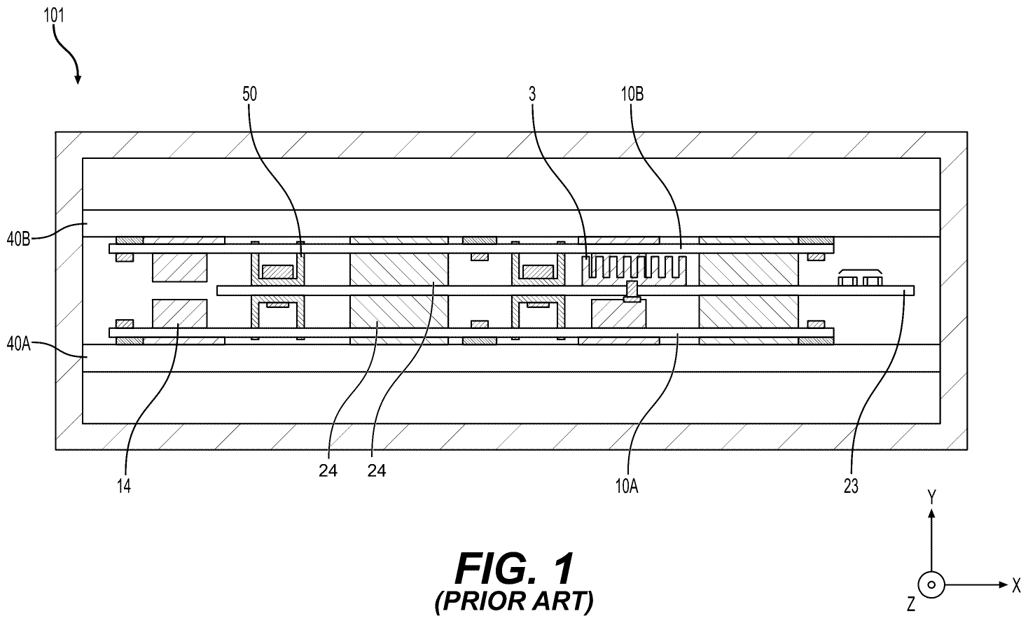

### DETAILED DESCRIPTION OF PREFERRED EMBODIMENTS

### First Preferred Embodiment

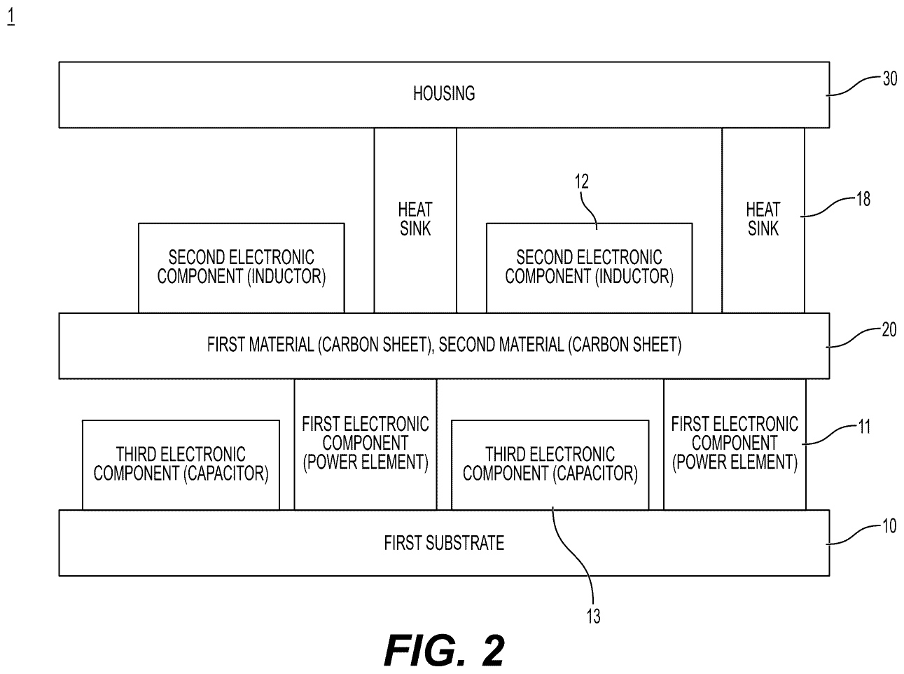

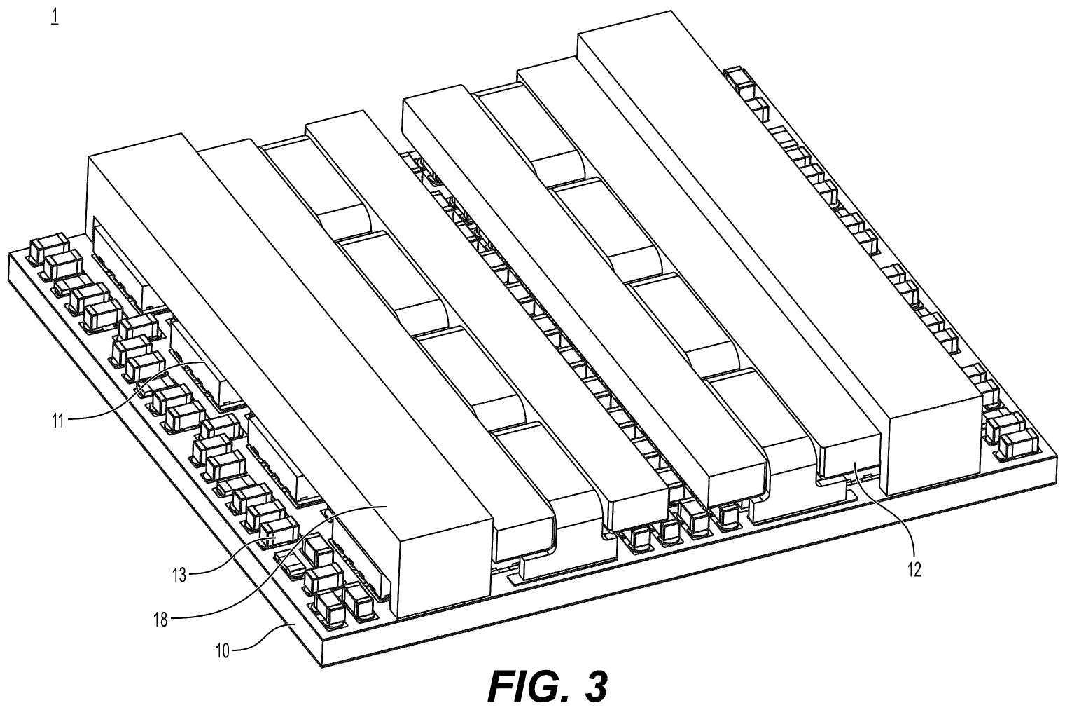

A power supply module according to a first preferred embodiment of the present invention will be described with reference to FIGS. 2 and 3. FIG. 2 is a cross-sectional block diagram showing an example of an arrangement of components of a power supply module 1 according to the first preferred embodiment of the present invention. FIG. 3 is a perspective view of an example of a power supply module 1 according to the first preferred embodiment of the present invention with the housing removed to show a possible arrangement of the components of the power supply module 1.

As shown in FIG. 2, a power supply module 1 can include a first substrate 10, a thermally conductive layer 20 (which can include at least one layer of material), a housing 30, a first electronic component 11, a second electronic component 12, a third electronic component 13, and a heat sink 18.

At least one first electronic component 11 and one third electronic component 13 are provided on a principal surface of the first substrate 11. Multiple first electronic components 11 and multiple third electronic components 13 can be provided on the principal surface of the first substrate 11. The first electronic components 11 can be higher-heat-generating elements. For example, the first electronic components 11 can be power elements such as, for example, transistors, op-amps, inverters, diodes, etc. The third electronic components 13 can be smaller, lower-heat-generating elements. For example, the third electronic components 13 can be capacitors such as, for example, surface mount chip capacitors.

The heat sink 18 can be a single heat sink or can be divided into multiple heat sinks that may or may not be in thermal contact with each other. The heat sink 18 can be made of a material that conducts heat, such as a metal, including, for example, Al, Cu, brass, or at least one alloy of Al, Cu, brass. The heat sink 18 can be manufactured by cutting, press working, die casting, etc. The heat sink 18 can be fixed onto a product by using an adhesive, solder, etc. The heat sink 18 can be provided with protrusions that can be used to fix the heat sink 18 in place by hooking the protrusions onto ends of a substrate. Fixing of the heat sink 18 onto end of a substate and adhesion of the heat sink can be performed at the same position.

A thermal interface material (TIM) can be interposed between the heat sink 18 and the first electronic components 11.

The thermally conductive layer 20 can be provided on an upper surface of the first electronic components 11. Depending on the application, the thermally conductive layer 20 can have a thermal conductivity lower, higher, or the same as the thermal conductivity of the first substrate 10. The thermally conductive layer can include at least one material or layer or can include two or more materials or layers joined together. The at least one material or layer can include one or more kinds of carbon sheets, for example.

At least one second electronic component 12 and a heat sink 18 are provided on a principal surface of the thermally conductive layer 20. Multiple second electronic components 12 and the heat sink 18 can be provided on the thermally conductive layer 20. The second electronic components 12 can be a larger, lower-heat-generating elements. For example, the second electronic components 12 can be inductors, which can have lower thermal conductivity than the heat sink 18. The first electronic elements 11 and the second electronic elements 12 can be larger than the third electronic elements 13. Arranging lower-heat-generating elements, such as inductors, and the heat sink on the same layer, while overlapping from a top view the larger electronic elements, such as the power elements and inductors, and overlapping from the top view the higher-heat-generating elements, such as the power elements, and the heat sink, helps achieve miniaturization (e.g., smaller footprint), while providing sufficient thermal coupling between the high-heat-generating elements and the heat sink.

Another TIM can be interposed between the portion of each of the first electronic components 11 that overlaps a lower portion of the second electronic component 12. The thermal resistance can be large, even when thermally coupled to the second electronic component 12. Thus, a thermally conductive layer 20 can be interposed between the first electronic component and the lower portion of the second electronic component to facilitate diffusion of heat to the heat sink 18.

The first electronic components 11, the second electronic components 12, and the heat sink 18 can be arranged such that (i) portions of the first electronic components 11 and the heat sink 18 overlap one another when seen from a top view of the power supply module 1, and (ii) portions of the first electronic components 11 and the second electronic components 12 overlap one another when seen from a top view of the power supply module 1. Alternatively, the first electronic components 11, the second electronic components 12, and the heat sink 18 can be arranged such that (i) a portion of one first electronic component 11 and the heat sink 18 overlaps one another when seen from a top view of the power supply module 1, and (ii) a portion of the first electronic component 11 and a portion of a second electronic component 12 overlap one another when seen from a top view of the power supply module 1. The first electronic component(s) 11 and the heat sink 18 can overlap by any overlap percentage. Because of these arrangements, and due to the thermally conductive layer 20, both of the first electronic components 11 and the second electronic components 12 are efficiently thermally connected to the heat sink 18. While inductors typically have low thermal conductivity, the inclusion of the thermally conductive layer 20 provides a path for heat to move from the second electronic components 12 to the heat sink 18. This efficient thermal connection produces an improved cooling effect, such that a performance of the power supply module 1 is improved and greater current outputs are possible.

Additionally, the first electronic components 11 and the third electronic components 13 may or may not, depending on the particular application, overlap one another when viewed from a side of the power supply module 1. The second electronic components 12 and the heat sink 18 may or may not, depending on the particular application, overlap one another when viewed from a side of the power supply module 1.

Since the first electronic components 11, the second electronic components 12, and the heat sink 18 can be arranged in an overlapping arrangement in the top view of the power supply module 1, it is possible to reduce a surface area of the first substrate 10, thereby aiding in miniaturizing the power supply module 1.

The heat sink 18 can be made of a material that is both thermally and electrically conductive. Suitable materials for the heat sink 18 include, for example, copper, aluminum, or other suitable material. A top surface of the heat sink 18 can be located higher than a top surface of the second electronic components 12. This arrangement allows heat to more easily escape to the outside of the power supply module 1 by defining a clearance between the housing 30, which can be in contact with the upper surface of the heat sink 18 but not the second electronic components 12, and the second electronic components 12. Further, this arrangement also helps avoid malfunctions which may be caused by, for example, short circuiting or static electric discharge between the housing 30 and the second electronic components 12. The housing 30 can be made of, for example, aluminum, steel, copper, brass, or other suitable material.

To further aid in heat dissipation, it is possible to have a top surface of the second electronic components 12 and/or a top surface of the heat sink 18 at least partially molded or embedded within a portion of the housing 30 to enhance thermal conductivity between the housing 30, the second electronic components 12, and the heat sink 18.

FIG. 3 shows a perspective view of an example of a power supply module 1 according to the first preferred embodiment of the present invention with the housing removed. The housing is not shown in FIG. 3. Here, first electronic components 11 (power elements) and third electronic components 13 (chip capacitors) are provided on a principal surface of the first substrate 10. A thermally conductive layer 20 (not visible in FIG. 3 as it is overlapped by other components) is provided on an upper surface of the first electronic components 11 which is then contacted by lower surfaces of the second electronic components 12 (inductors) and the heat sink 18.

### Second Preferred Embodiment

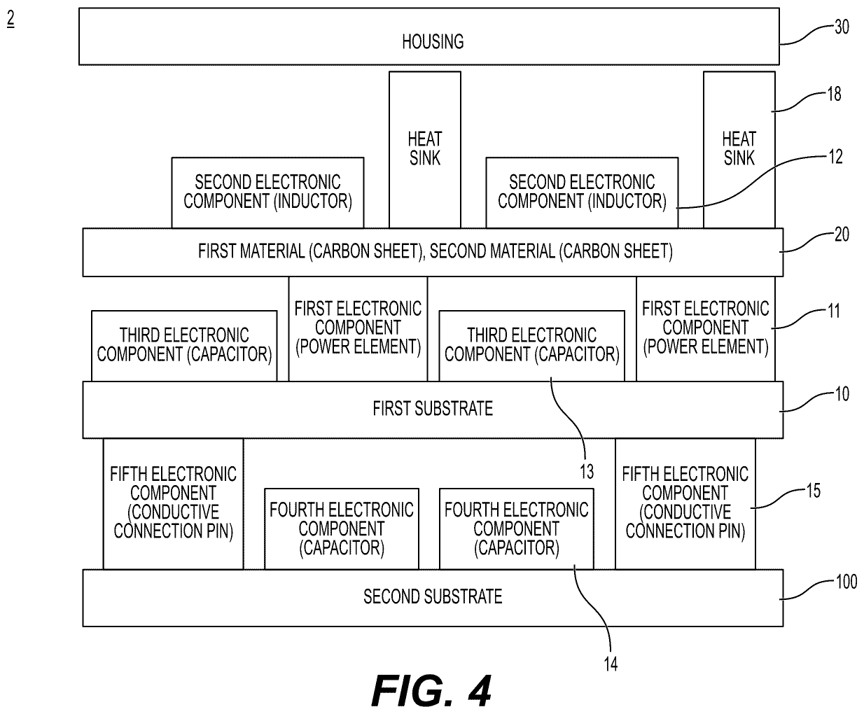

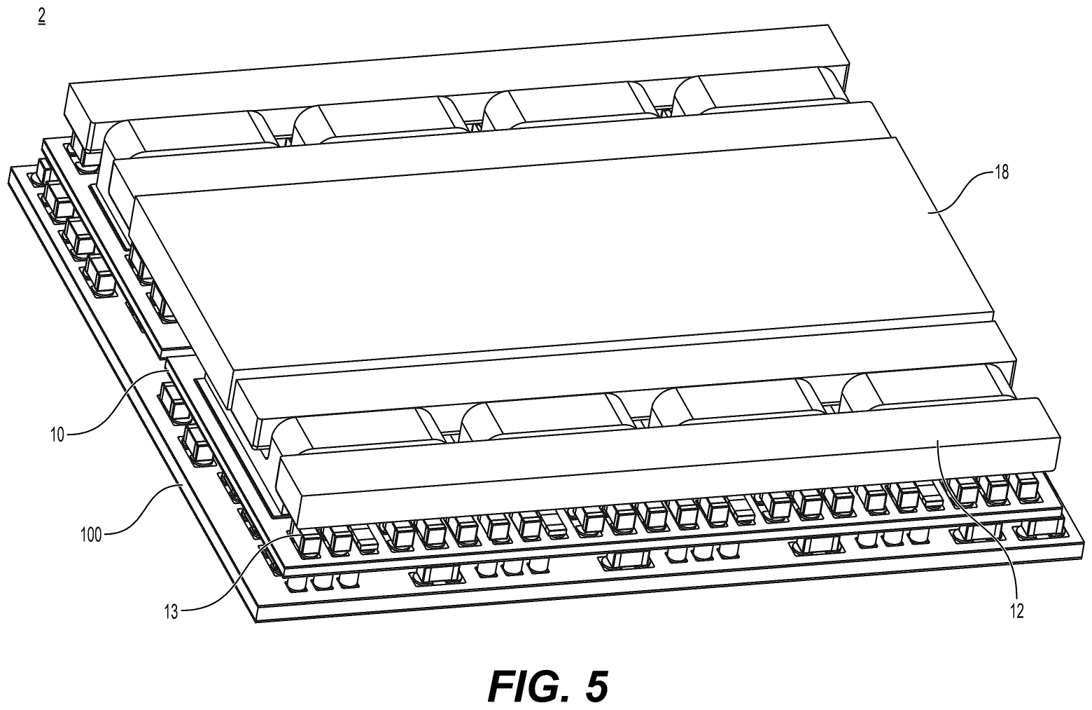

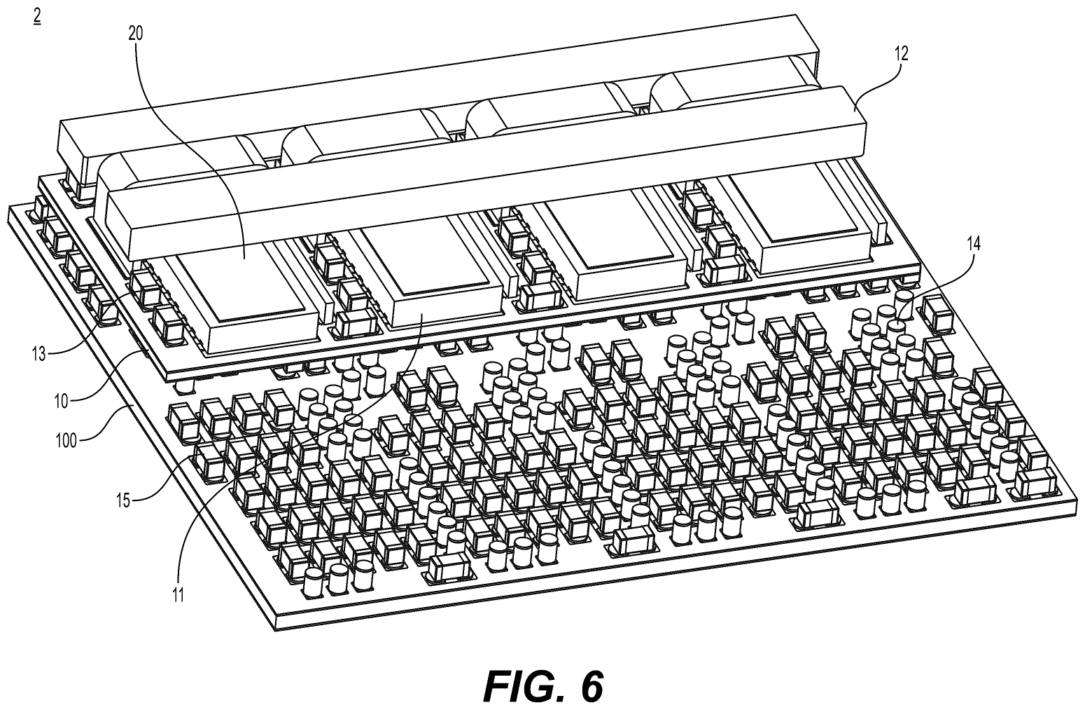

A power supply module according to a second preferred embodiment of the present invention will be described with reference to FIGS. 4-7. FIG. 4 is a cross-sectional block diagram showing an example of an arrangement of components of a power supply module 2 according to the second preferred embodiment of the present invention. FIG. 5 is a perspective view of an example of a power supply module 2 according to the second preferred embodiment of the present invention with the housing removed to show a possible arrangement of the components of the power supply module 2. The housing is not shown in FIG. 5. FIG. 6 is another perspective view of an example of a power supply module 2 according to the second preferred embodiment of the present invention which also includes one of the first substrates 10 removed for the sake of showing a possible arrangement of components of the power supply module 2. The housing is not shown in FIG. 6.

As illustrated in FIG. 4, the power supply module 2 according to the second preferred embodiment is different from the power supply module 1 according to the first preferred embodiment in that a first substrate 10 and a second substrate 100 are provided in a stacked arrangement. The first substrate 10 can be stacked on top of the second substrate 100. The first substrate 10 can be a single substrate or, as shown in FIGS. 5 and 6, the first substrate 10 can include two or more first substrates 10. Other configurations of the power supply module 2 according to the second preferred embodiment can be the same as those of the power supply module 1 according to the first preferred embodiment, and a description of the same portions is omitted for the sake of brevity.

The first substate 10, the first electronic components 11, the second electronic components 12, the third electronic components 13, the heat sink 18, the thermally conductive layer 20, and the housing 30 of the second preferred embodiment can be arranged the same or similar as in the first preferred embodiment. The first substrate 10 can be mounted to the second substrate 100 with the fourth electronic components 14 and the fifth electronic components 15 between the first substrate 10 and the second substrate 100. The fourth electronic components 14 can include smaller, lower-heat-generating element, including, for example, capacitors, and the fifth electronic component 15 can include, for example, contact pins or other suitable connector(s) that connect the first substrate 10 and the second substrate 100.

The power supply module 2 can include a stack of substrates defined by the first substrate 10 and the second substrate 100. The first substrate 10 includes at least one third electronic component 13 provided on a principal surface of the first substrate 10. The second substrate 200 includes at least one fifth electronic component 15 provided on a principal surface of the second substrate 200. This arrangement allows miniaturization of the power supply module 2, especially in the case when additional chip capacitors are used in the power supply module 2.

The first substrate 10 can include at least one first electronic component 11 and one third electronic component 13 on a principal surface, with at least one second electronic component 12 and a heat sink 18 being provided on a principal surface of a thermally conductive layer 20 on the first electronic component 11. As with the power supply module 1, in the power supply module 2, the first electronic components 11, the second electronic components 12, and the heat sink 18 can be arranged such that (i) portions of the first electronic components 11 and the heat sink 18 overlap one another when seen from a top view of the power supply module 2, and (ii) portions of the first electronic components 11 and the second electronic components 12 overlap one another when seen from a top view of the power supply module 2. Alternatively, the first electronic components 11, the second electronic components 12, and the heat sink 18 can be arranged such that (i) a portion of a first electronic component 11 and the heat sink 18 overlap one another when seen from a top view of the power supply module 2, and (ii) a portion of the first electronic component 11 and a portion of a second electronic component 12 overlap one another when seen from a top view of the power supply module 2.

The inclusion of the stack of substrates defined by the first substrate 10 and the second substrate 100 in the power supply module 2 makes it possible to include additional components in a smaller footprint However, by including the specific arrangements of the power supply module 2, it is possible to provide an efficient thermal connection which produces improved cooling, such that a performance of the power supply module 2 is improved, and greater current outputs are possible.

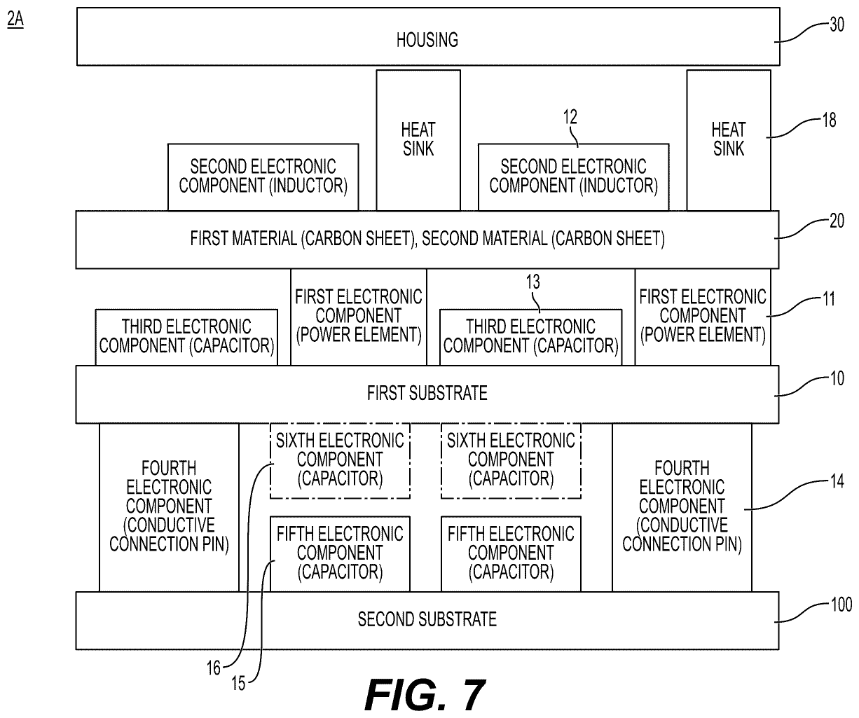

FIG. 7 shows a modification to the power supply module 2A in which sixth electronic components 16 can be provided on a lower surface of the first substrate 10. This arrangement allows for even further miniaturization while maintaining the improved cooling.

The first substate 10, the second substrate 100, the first electronic components 11, the second electronic components 12, the third electronic components 13, the fourth electronic components 14, and the fifth electronic components 15, the heat sink 18, the thermally conductive layer 20, and the housing 30 of the modification of the second preferred embodiment can be arranged the same or similar as in the second preferred embodiment. The sixth electronic components can be added to the bottom surface of the first substrate 10. The sixth electronic component 15 can be smaller, lower-heat-generating element, including, for example, capacitors.

### Third Preferred Embodiment

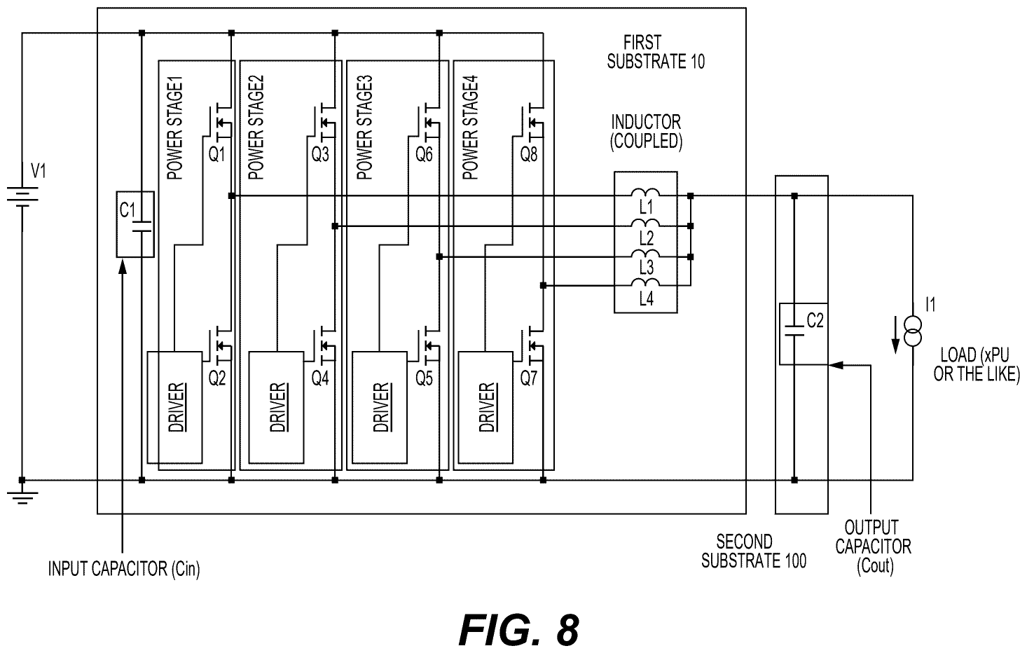

FIG. 8 shows a circuit diagram of a power supply module according to a third preferred embodiment of the present invention. The circuit diagram can be implemented in the power supply module according to the other preferred embodiments, including the first and the second preferred embodiments discussed above and the fourth and the fifth preferred embodiments discussed below. The circuit diagram of FIG. 8 is just one example, and the power supply modules of the other preferred embodiments can implement other power supply circuits or topologies.

The circuit diagram includes an input voltage V1, an input capacitor Cin, power stages 1, 2, 3, 4, inductors L1, L2, L3, L4, output capacitor Cout, and load 11. The input voltage V1 is connected to the input capacitor Cin. The power stages 1, 2, 3, 4 are connected to the input capacitor Cin. Although FIG. 8 shows four power stages, any number of power stages can be used. Each power stage 1, 2, 3, 4 includes a driver that drives two power switches Q1 & Q2, Q3 & Q4, Q5 & Q6, Q7 & Q8. Different topologies can have a different number of power switches in each stage. Each power stage 1, 2, 3, 4 can be connected to a corresponding inductor L1, L2, L3, L4. The number of inductors can match the number of power stages. As shown in FIG. 8, the inductors L1, L2, L3, L4 can be coupled. The inductors can be coupled by sharing a common core, as shown, for example, in FIG. 6. In some applications, the inductors might not be coupled. The inductors L1, L2, L3, L4 are connected to the output capacitor Cout. The load 11 is connected to the output capacitor Cout.

The various components in the circuit diagram can be located in different areas of the power supply module. For example, the components of the power stages 1, 2, 3, 4, including the drivers and the power switches Q1 & Q2, Q3 & Q4, Q5 & Q6, Q7 & Q8, can be the first electronic components 11 on the first substrate 10; the inductors L1, L2, L3, L4 can be the second electronic components 12 located above and at least partially overlapping with the first electronic components 11; and the input capacitor Cin and the output capacitor Cout can be the third electronic components 13 on the first substrate 10 or, as shown in FIG. 8, can be the fifth electronic components 15 and sixth electronic components 16 between the first substrate 10 and the second substrate 100. The electronic components located on different substrates can be connected using the fourth electronic components 14.

### Fourth Preferred Embodiment

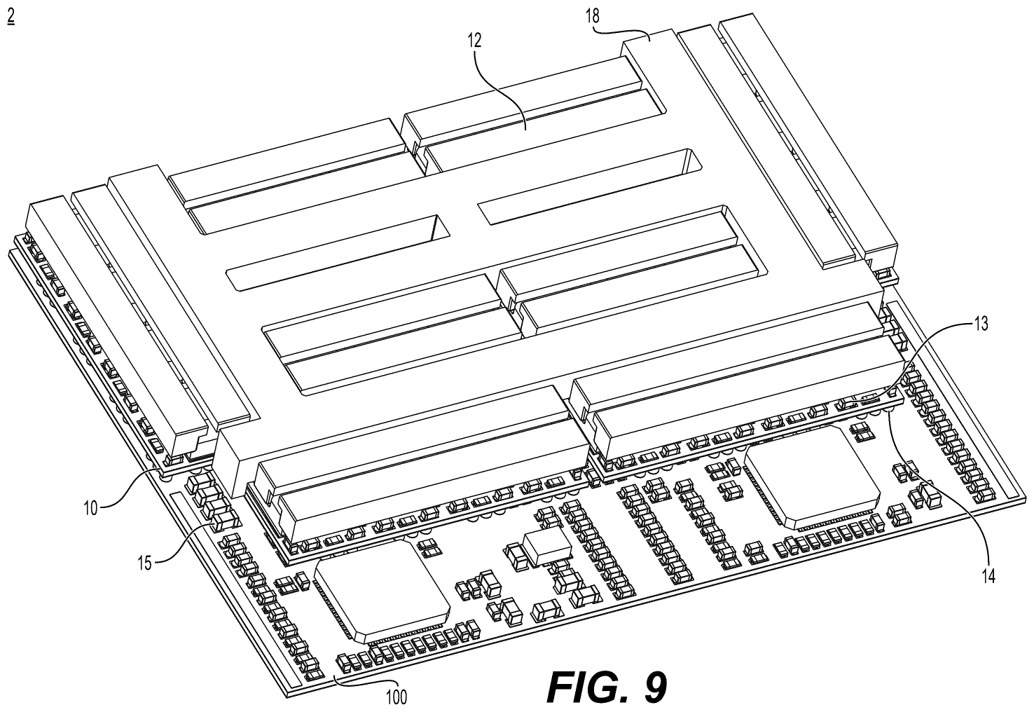

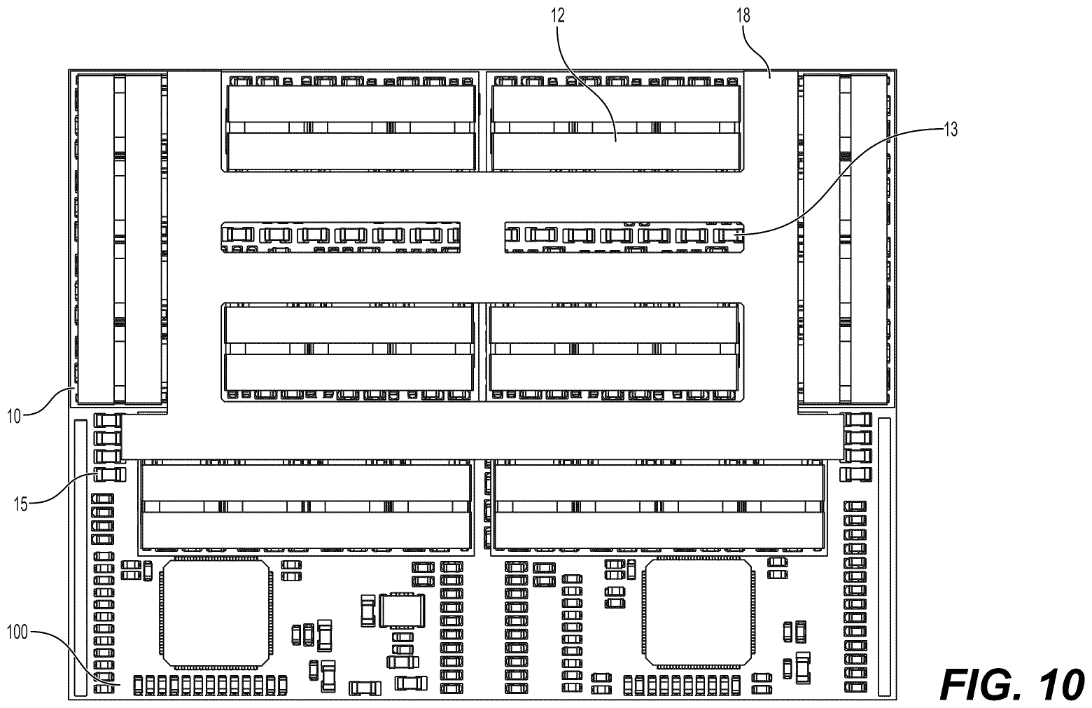

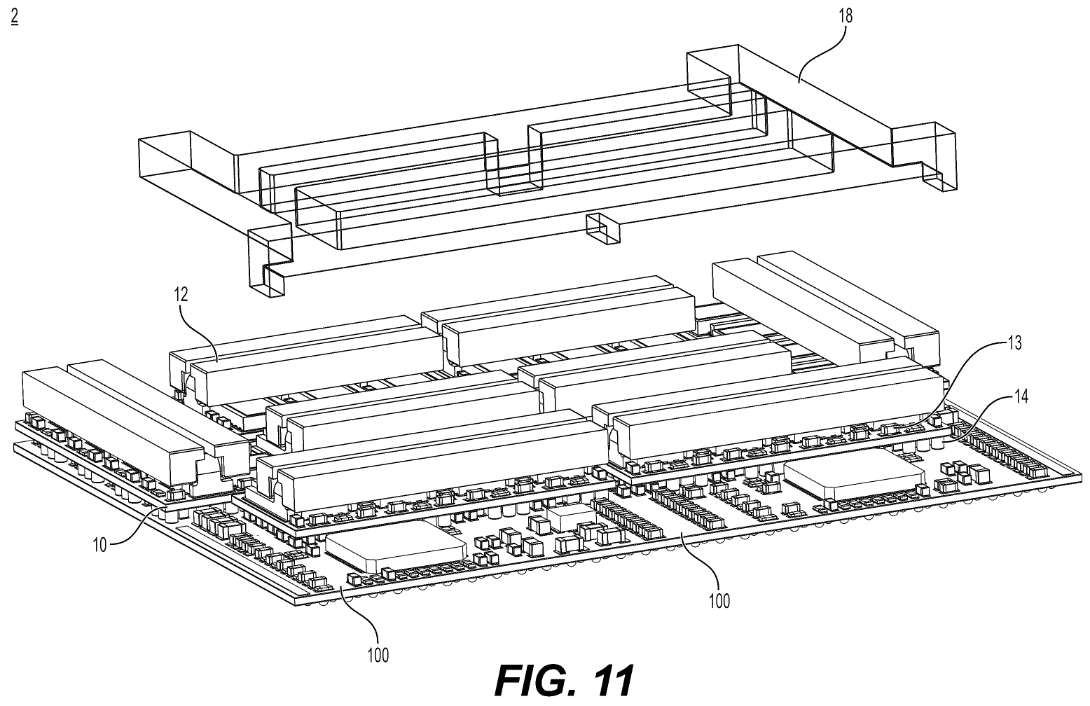

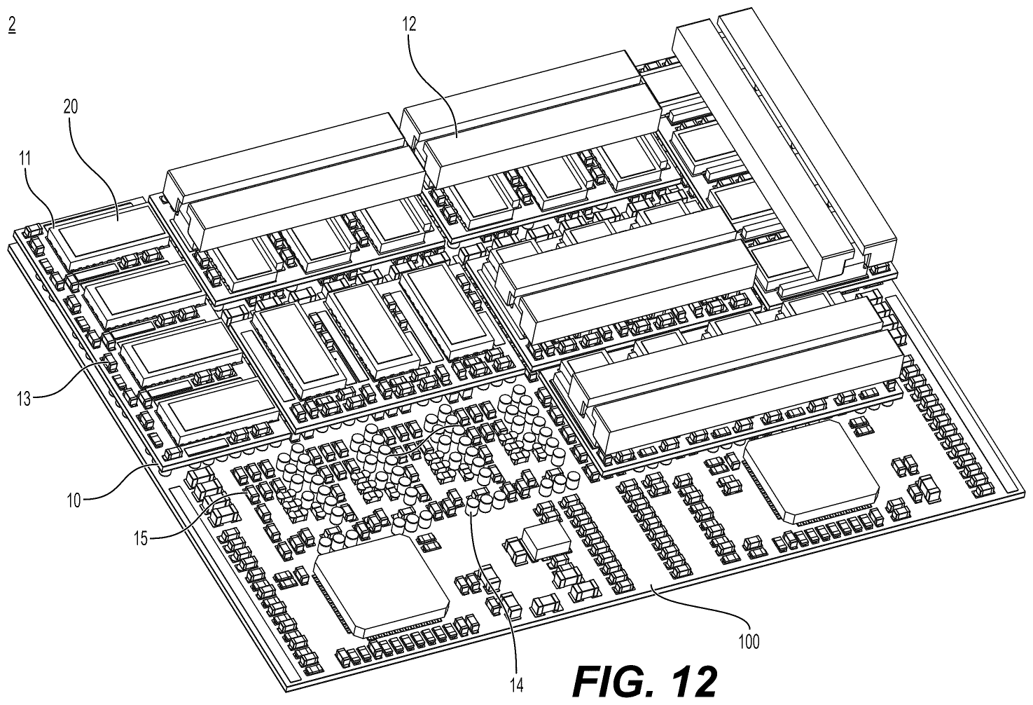

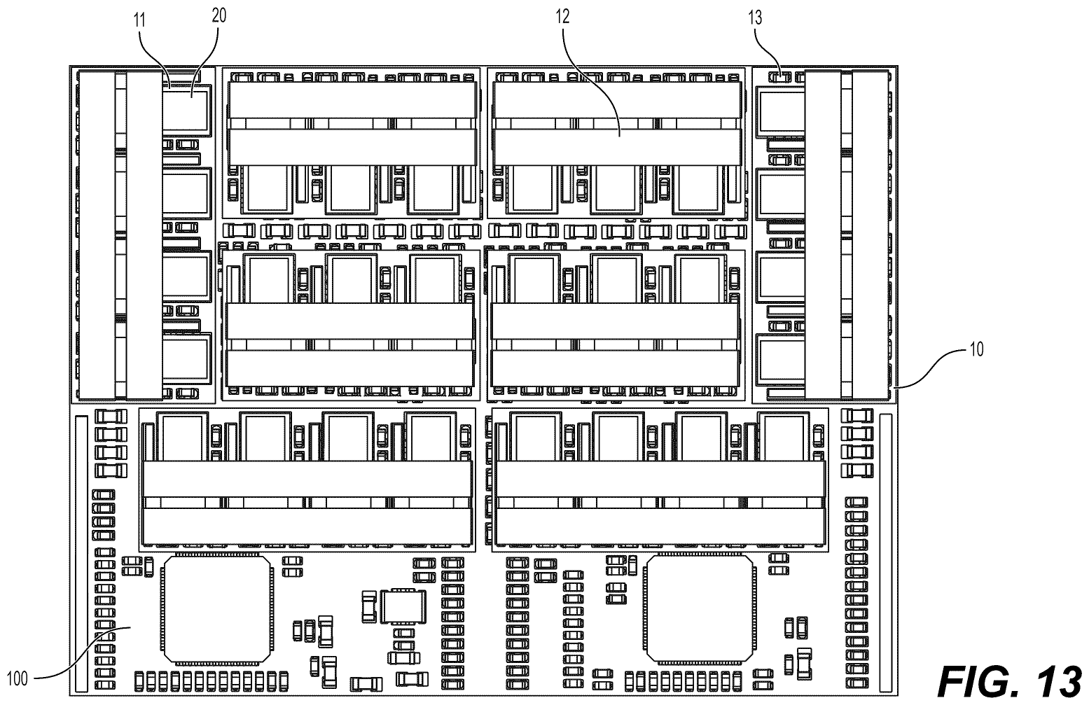

FIGS. 9-13 show a power supply module 2 according to a fourth preferred embodiment of the present invention. The power supply module 2 of FIGS. 9-13 is similar to the power supply module 2 of the second preferred embodiment but includes eight first substrates 10 over a second substrate 100. FIGS. 9 and 10 show the power supply module 2 without a housing but including a single heat sink 18. FIG. 11 is an exploded view showing the heat sink 18 above the first substrates 10. FIGS. 12 and 13 show the power supply module 2 without the heat sink 18. FIG. 12 additionally does not show one of the first substrates 10 and does not show the inductors on two of the other first substrates 10.

The heat sink 18, the first electronic component 11, the second electronic component 12, and the third electronic component 13 are located above the first substrates 10. As shown in FIGS. 9 and 10, a single heat sink 18 can be located over all eight first substrates 10, while each of the first substrates 10 can include separate first electronic components 11, second electronic components 12, and third electronic components 13. The fourth electronic components 14 can connect the different first substrates 10 to the second substrate 100. The fifth electronic component 15 (e.g., a capacitor) and possibly a sixth electronic component (e.g., a capacitor) (not shown in FIGS. 9-13) can be located between a corresponding one of the first substrates 10 and the second substrate 100.

As shown in FIGS. 9-13, the second substrate 100 can include an area or areas in which the second substrate 100 is not covered by a corresponding first substrate 10. Additional electronic components can be included in this uncovered area. The additional electronic components can control, for example, the first electronic components 11. For example, if the first electronic components include powers stages with power switches and drivers of the power switches, then the additional electronic components can include a controller that sends control signals to the drivers of the power stages.

### Fifth Preferred Embodiment

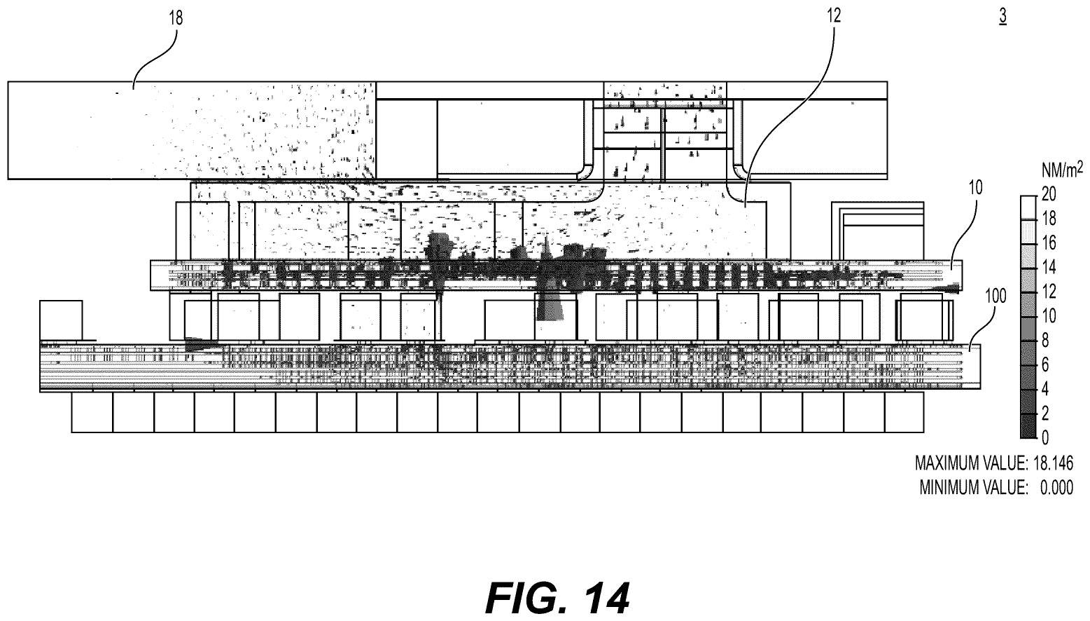

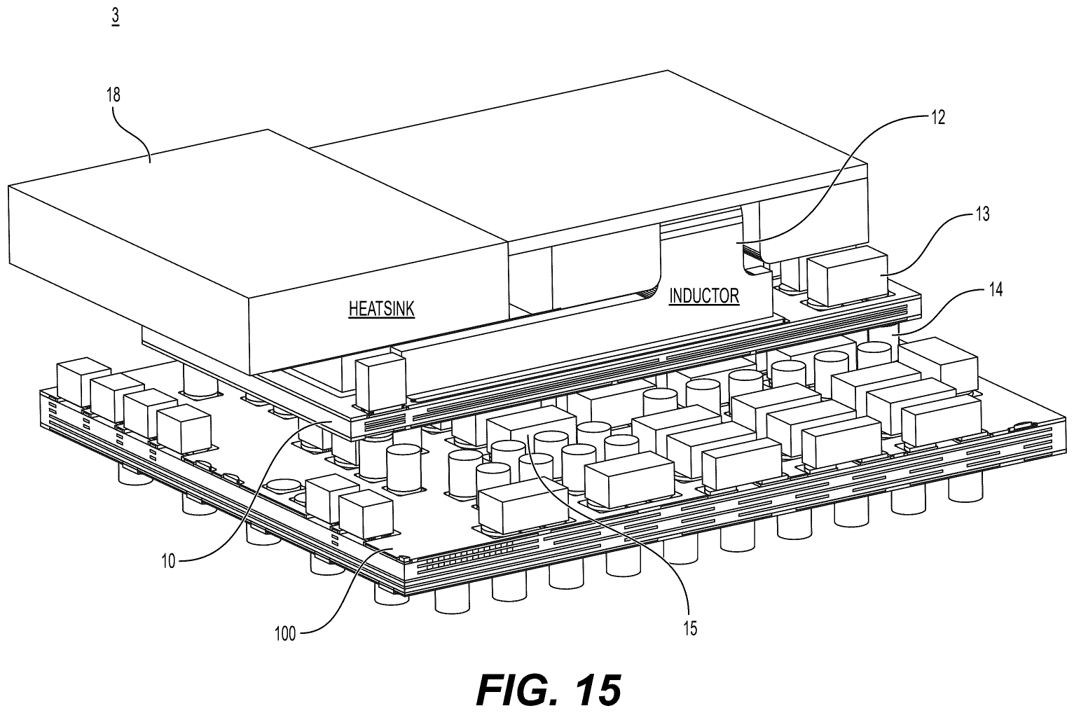

FIG. 14 shows a heatmap of the power supply module 3 according to a fifth preferred embodiment of the present invention of FIG. 15. The power supply module 3 is similar to the power supply module 2 of the second preferred embodiment that includes a first substrate 10 over a second substrate 100. The heat sink 18, the first electronic component 11 (e.g., a power element), the second electronic component 12 (e.g., an inductor), and the third electronic component 13 (e.g., a capacitor) are located above the first substrate 10. The fourth electronic components 14 can connect the first substrate 10 and the second substrate 100. The fifth electronic component 15 (e.g., a capacitor) can be located between the first substrate 10 and the second substrate 100.

The heatmap of FIG. 14 shows that overlapping both the second electronic component 12 and the heat sink 18 with the first electronic component 11 allows heat to flow from the first electronic component 11 and the second electronic component 12 to the heat sink 18.

The configurations of the preferred embodiments and modifications described above can appropriately be combined with each other, and effects corresponding to the respective combinations can be achieved.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1. A power supply module comprising:
a first substrate;
first electronic components on a principal surface of the first substrate;
second electronic components above the first electronic components; and
a heat sink located above the first electronic components; wherein the first electronic components and the second electronic components are thermally connected;
the first electronic components and the heat sink are thermally connected;
from a top view of the power supply module, at least a portion of one first electronic component of the first electronic components overlaps with at least a portion of one second electronic component of the second electronic components;
from the top view of the power supply module, at least a portion of the one first electronic component overlaps with a portion of the heat sink; and
from a side view of the power supply module, the second electronic components do not overlap any portion of the heat sink.

2. The power supply module according to claim 1, wherein the first electronic components include power elements.

3. The power supply module according to claim 1, further comprising third electronic components on the principal surface of the first substrate.

4. The power supply module according to claim 3, wherein the third electronic component include capacitors.

5. The power supply module according to claim 1, further comprising a first thermally conductive material between the first electronic components and the second electronic components.

6. The power supply module according to claim 5, wherein the first thermally conductive material includes a first carbon sheet.

7. The power supply module according to claim 5, further comprising a second thermally conductive material between the first electronic components and the heat sink.

8. The power supply module according to claim 7, wherein the second thermally conductive material includes a second carbon sheet.

9. The power supply module according to claim 7, wherein the first thermally conductive material and the second thermally conductive material define a single layer.

10. The power supply module according to claim 1, wherein the second electronic components include inductors.

11. The power supply module according to claim 10, wherein a top surface of the heat sink is located above a top surface of the inductors.

12. The power supply module according to claim 1, wherein the heat sink has electrical conductivity and thermal conductivity.

13. The power supply module according to claim 1, wherein a top surface of the second electronic components and/or a top surface of the heat sink are at least partially molded within a housing.

14. A power supply module comprising:
first and second substrates, the first substrate is located above the second substrate;
first electronic components on a principal surface of the first substrate;
second electronic components above the first electronic components;
fourth electronic components on a principal surface of the second substrate; and
a heat sink above of the first electronic components; wherein
the first electronic components and the second electronic components are thermally connected;
the first electronic components and the heat sink are thermally connected;
from a top view of the power supply module, at least a portion of one first electronic component of the first electronic components overlaps a portion of one second electronic component of the second electronic components;
from the top view of the power supply module, at least a portion of the one first electronic component overlaps a portion of the heat sink; and
from a side view of the power supply module, the second electronic components do not overlap any portion of the heat sink.

15. The power supply module according to claim 14, wherein the fourth electronic components include capacitors.

16. The power supply module according to claim 14, further comprising conductive connection pins connecting the first and the second substrates.

17. The power supply module according to claim 14, further comprising third electronic components provided on the principal surface of the first substrate.

18. The power supply module according to claim 17, wherein the third electronic components include capacitors.

19. The power supply module according to claim 14, further comprising sixth electronic components provided on another principal surface of the first substrate opposing the principal surface of the first substrate where the first electronic components are provided.

20. The power supply module according to claim 19, wherein the sixth electronic component include capacitors.
